(19) United States
(12) Patent Application Publication
(10) Pub. No.: US 2025/0056852 A1
(43) Pub. Date: Feb. 13, 2025

(54) SOURCE/DRAIN REGIONS IN COMPLEMENTARY FIELD EFFECT TRANSISTORS AND METHODS OF FORMING THE SAME

(71) Applicant: Taiwan Semiconductor Manufacturing Co., Ltd., Hsinchu (TW)

(72) Inventors: Yu-Chang Lin, Hsinchu (TW); Liang-Yin Chen, Hsinchu (TW); Chi On Chui, Hsinchu (TW)

(21) Appl. No.: 18/447,913

(22) Filed: Aug. 10, 2023

(51) Int. Cl. H01L 29/08; H01L 21/8238; H01L 27/092; H01L 29/06; H01L 29/423; H01L 29/66; H01L 29/775; H01L 29/78; H01L 29/786

(52) U.S. Cl. CPC H01L 29/0847; H01L 21/823807; H01L 21/823814; H01L 27/0922; H01L 29/0673; H01L 29/42392; H01L 29/66439; H01L 29/775; H01L 29/7848; H01L 29/78696

(57) ABSTRACT

A method includes forming first nanostructures over a substrate, then forming second nanostructures over the plurality of first nanostructures. A first source/drain region is epitaxially grown adjacent the first nanostructures, and a second source/drain region is epitaxially grown over the first source/drain region and adjacent the second nanostructures. An implantation process is performed to implant impurities into the second source/drain region, wherein the implantation process forms an amorphous region within the second source/drain region. At least one rapid thermal process is performed on the second source/drain region, wherein performing each rapid thermal process recrystallizes a portion of the amorphous region.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example schematic of a complementary field-effect transistor (CFET) in a three-dimensional view, in accordance with some embodiments.

FIGS. 2, 3, 4, 5, 6, 7, 8A, 8B, and 8C are views of intermediate stages in the manufacturing of CFETs, in accordance with some embodiments.

FIGS. 9A, 9B, 9C, 9D, and 9E illustrate intermediate steps in the formation of epitaxial source/drain regions, in accordance with some embodiments.

FIGS. 10, 11, 12A, 12B, 12C, and 13 are views of intermediate stages in the manufacturing of CFETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, complementary field-effect transistors (CFETs) are formed. A CFET includes a lower nanostructure-FET and an upper nanostructure-FET. A lower source/drain region of the lower nanostructure-FET is formed before an upper source/drain region of the upper nanostructure-FET. The lower source/drain region and the upper source/drain region may stress adjacent channel regions to improve performance. The upper source/drain region is formed by implanting dopants that amorphize a portion of the upper source/drain region followed by a rapid thermal process that recrystallizes the amorphized portion. Forming the upper source/drain region in this manner allows dopants within the upper source/drain region to be activated while keeping the lower source/drain region below a relaxation temperature. Activating the dopants of the upper source/drain region using the techniques described herein improves device performance without causing thermally-induced relaxation of the lower source/drain region, which can degrade device performance. As a result, device performance and manufacturing ease of the completed CFETs can be improved.

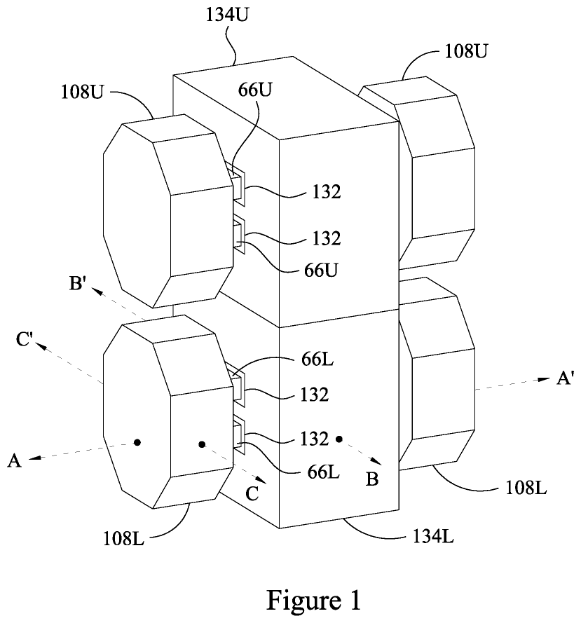

FIG. 1 illustrates an example schematic of a stacked transistor, such as a complementary field-effect transistor (CFET), in accordance with some embodiments. FIG. 1 is a three-dimensional view, where some features of the CFETs are omitted for illustration clarity.

The CFETs include multiple vertically stacked nanostructure-FETs (e.g., nano-FETs, nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, in some embodiments, the CFET may include a lower PMOS transistor and an upper NMOS transistor. In other embodiments, the CFET may include a lower NMOS transistor and an upper PMOS transistor. Each of the nanostructure-FETs include semiconductor nanostructures 66 (labeled lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIG. 1) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (labeled lower source/drain regions 108L and upper source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer (not explicitly illustrated in FIG. 1). Alternatively, a lower gate electrode 134L may be coupled to an upper gate electrode 134U. Further, the upper source/drain regions 108U may be separated from lower source/drain regions 108L by one or more dielectric layers (not explicitly illustrated in FIG. 1). The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures refer to these reference cross-sections for clarity.

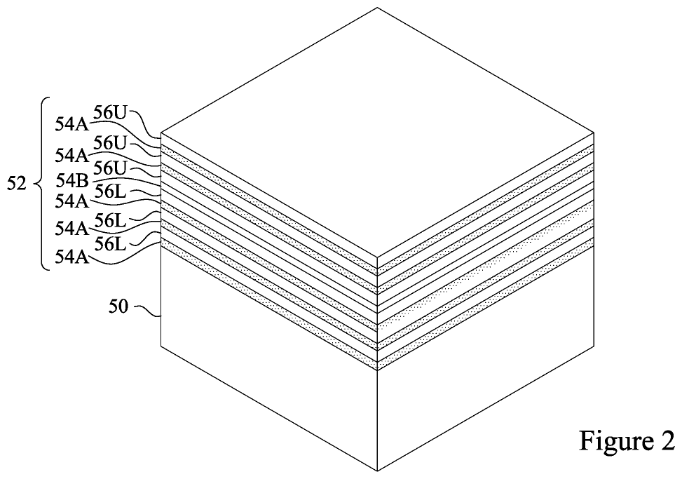

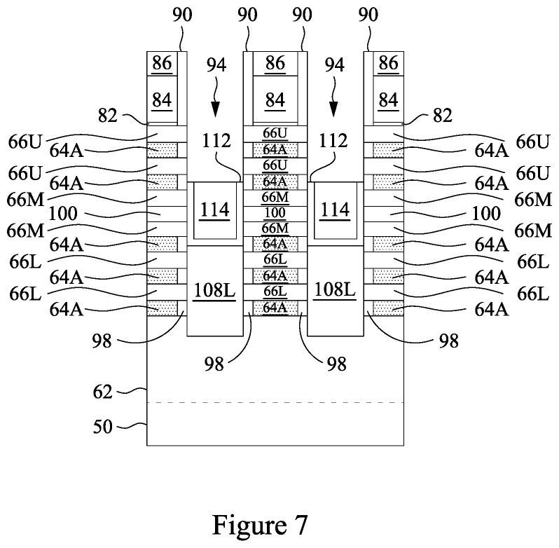

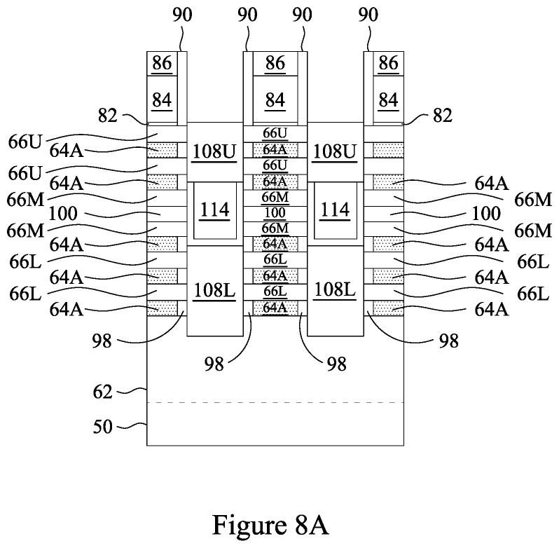

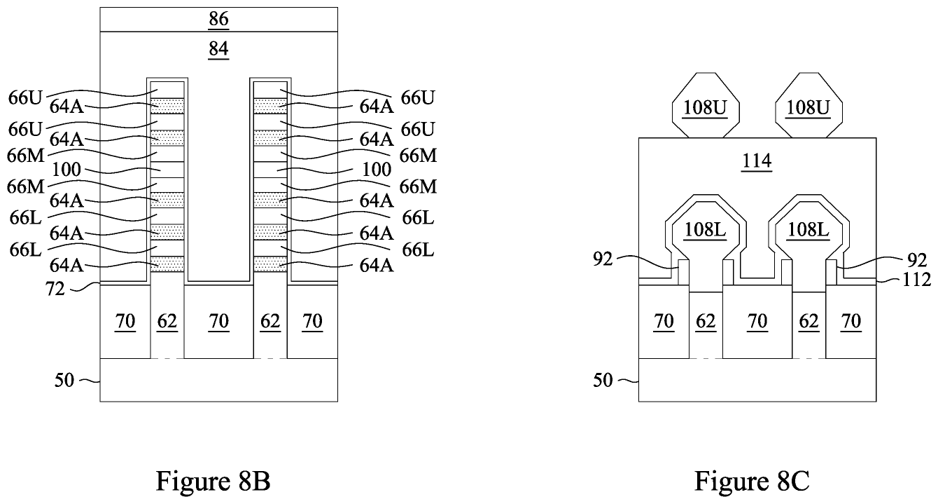

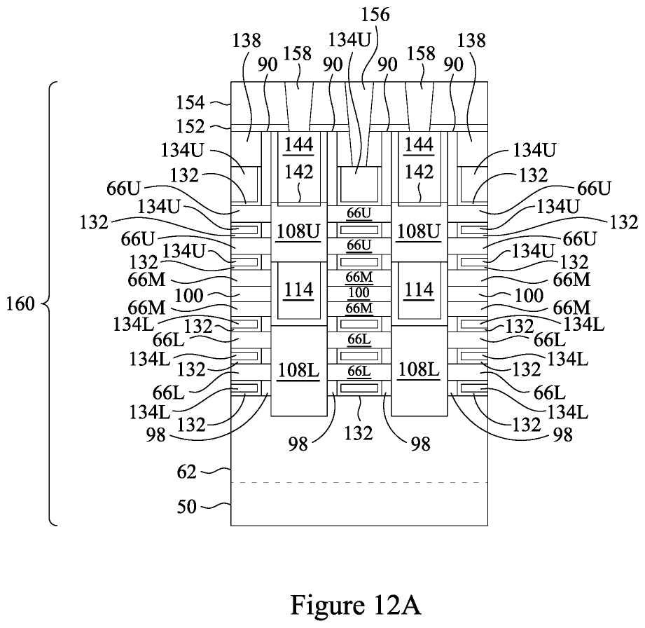

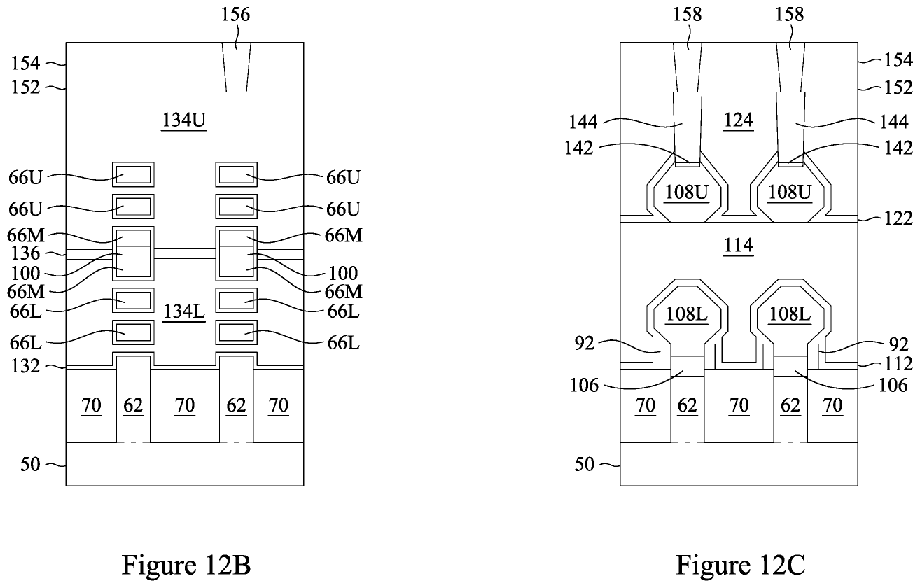

FIGS. 2-13 are views of intermediate stages in the manufacturing of CFETs, in accordance with some embodiments. FIGS. 2, 3, and 4 are three-dimensional views showing a similar three-dimensional view as FIG. 1. FIGS. 7, 8, 9A, 9B, 9C, 9D, 9E, 10, 11, 12A, and 13 illustrate cross-sectional views along a similar cross-section as reference cross-section A-A′ in FIG. 1. FIGS. 8B and 12B illustrate cross-sectional views along a similar cross-section as reference cross-section B-B′ in FIG. 1. FIGS. 8C and 12C illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. For example, the substrate 50 may be a multi-layered substrate that includes a layer of a semiconductor material formed on a silicon-germanium layer, where the silicon-germanium layer is provided on a substrate core, typically a silicon or glass substrate.

A multi-layer stack 52 is formed over the substrate 50. The multi-layer stack 52 includes alternating dummy semiconductor layers 54 (including first dummy semiconductor layers 54A and a second dummy semiconductor layer 54B) and semiconductor layers 56 (including lower semiconductor layers 56L and upper semiconductor layers 56U). The lower semiconductor layers 56L and a subset of the first dummy semiconductor layers 54A are disposed below the second dummy semiconductor layer 54B. The upper semiconductor layers 56U and another subset of the first dummy semiconductor layers 54A are disposed above the second dummy semiconductor layer 54B. As subsequently described in greater detail, the dummy semiconductor layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including six of the dummy semiconductor layers 54 and six of the semiconductor layers 56. It should be appreciated that the multi-layer stack 52 may include any number of the dummy semiconductor layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy semiconductor layers 54A are formed of a first semiconductor material, the second dummy semiconductor layer 54B is formed of a second semiconductor material. The first and second semiconductor materials may be selected from the candidate semiconductor materials of the substrate 50. The first and second semiconductor materials have a high etching selectivity to one another. As such, the material of the second dummy semiconductor layer 54B may be removed at a faster rate than the material of the first dummy semiconductor layers 54A in subsequent processing. In some embodiments, the first dummy semiconductor layers 54A are formed of silicon-germanium having a low germanium concentration (e.g., a germanium concentration in the range of about 10% to about 40%) and the second dummy semiconductor layer 54B is formed of silicon-germanium having a high germanium concentration (e.g., a germanium concentration in the range of about 40% to about 50%).

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy semiconductor layers 54. As such, the materials of the dummy semiconductor layers 54 may be removed at a faster rate than the material of the semiconductor layers 56 in subsequent processing. In some embodiments, the semiconductor layers 56 are formed of silicon, which may be undoped or lightly doped at this step of processing. Other materials, combinations of materials, or compositions of materials are possible.

Some layers of the multi-layer stack 52 may be thicker than other layers of the multi-layer stack 52. The thickness of the second dummy semiconductor layer 54B may be different (e.g., greater or less) than the thickness of each of the first dummy semiconductor layers 54A. Additionally, the thickness of each of the semiconductor layers 56 may be different (e.g., greater or less) than the thickness(es) of each of the dummy semiconductor layers 54.

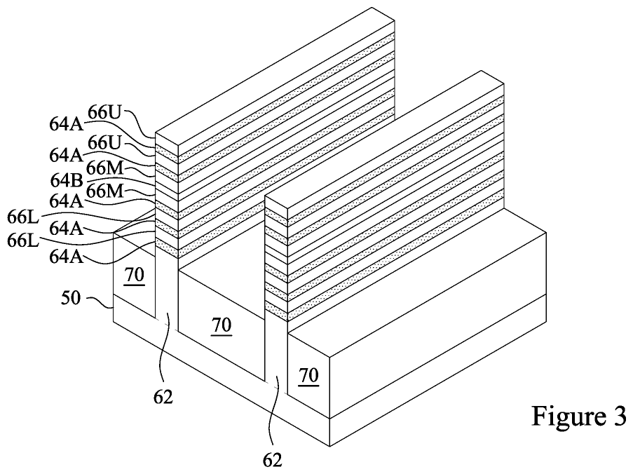

In FIG. 3, semiconductor fins 62 are formed in the substrate 50 and nanostructures 64/66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64/66 and the semiconductor fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may define the first dummy nanostructures 64A from the first dummy semiconductor layers 54A, the second dummy nanostructures 64B from the second dummy semiconductor layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may be collectively referred to as the dummy nanostructures 64. The lower semiconductor nanostructures 66L, the middle semiconductor nanostructures 66M, and the upper semiconductor nanostructures 66U may be collectively referred to as the semiconductor nanostructures 66.

As subsequently described in greater detail, the lower semiconductor nanostructures 66L will act as channel regions for lower nanostructure-FETs of the CFETs and the upper semiconductor nanostructures 66U will act as channel regions for upper nanostructure-FETs of the CFETs. The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. Further, in some embodiments, the second dummy nanostructures 64B may be subsequently replaced with isolation structures. In other embodiments, at least a portion of the second dummy nanostructures 64B may remain in the completed CFETs. The isolation structures and the middle semiconductor nanostructures 66M may define boundaries of the lower nanostructure-FETs and the upper nanostructure-FETs.

The semiconductor fins 62 and the nanostructures 64/66 may be patterned by any suitable method. For example, the semiconductor fins 62 and the nanostructures 64/66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the semiconductor fins 62 and the nanostructures 64/66. In some embodiments, a mask (or other layer) may remain on the nanostructures 64/66.

Although each of the semiconductor fins 62 and the nanostructures 64/66 are illustrated as having a constant width throughout, in other embodiments, the semiconductor fins 62 and/or the nanostructures 64/66 may have different widths or have non-constant widths. For example, in some embodiments, the semiconductor fins 62 and/or the nanostructures 64/66 may have tapered sidewalls such that a width of each of the semiconductor fins 62 and/or the nanostructures 64/66 continuously increases in a direction towards the substrate 50. In such embodiments, each of the nanostructures 64/66 may have a different width and be trapezoidal in shape. Other sidewall shapes or profiles are possible.

Further, isolation regions 70 are formed over the substrate 50 and between adjacent semiconductor fins 62. The isolation regions 70 may include a liner and a fill material over the liner, in some embodiments. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64/66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) may then be recessed such that upper portions of the semiconductor fins 62 and the nanostructures 64/66 extend higher than the isolation regions 70.

The previously described process is just one example of how the semiconductor fins 62 and the nanostructures 64/66 may be formed. In some embodiments, the semiconductor fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the semiconductor fins 62 and/or the nanostructures 64/66. The epitaxial structures may comprise the previously described semiconductor materials. In some embodiments in which epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the semiconductor nanostructures 66 and/or the semiconductor fins 62. For example, an n-type impurity implant and/or a p-type impurity implant may be performed, or the semiconductor materials may be in situ doped during growth. The n-type impurities may be phosphorus, arsenic, antimony, or the like at a concentration in a range from 10¹⁷ atoms/cm³ to 10¹⁹ atoms/cm³. The p-type impurities may be boron, boron fluoride, indium, or the like at a concentration in a range from 10¹⁷ atoms/cm³ to 10¹⁹ atoms/cm³. The wells in the lower semiconductor nanostructures 66L and the semiconductor fins 62 have a conductivity type opposite from a conductivity type of lower source/drain regions that will be subsequently formed adjacent the lower semiconductor nanostructures 66L. The wells in the upper semiconductor nanostructures 66U have a conductivity type opposite from a conductivity type of upper source/drain regions that will be subsequently formed adjacent the upper semiconductor nanostructures 66U.

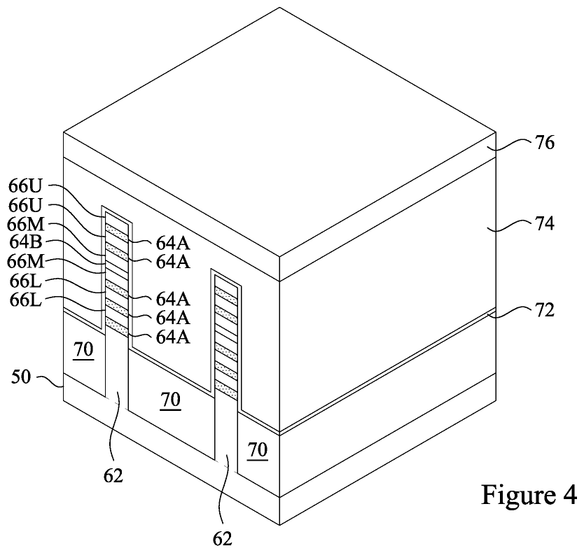

In FIG. 4, a dummy dielectric layer 72 is formed on the semiconductor fins 62 and/or the nanostructures 64/66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be made of other materials that have a high etching selectivity from the etching of isolation regions. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the semiconductor fins 62 and/or the nanostructures 64/66.

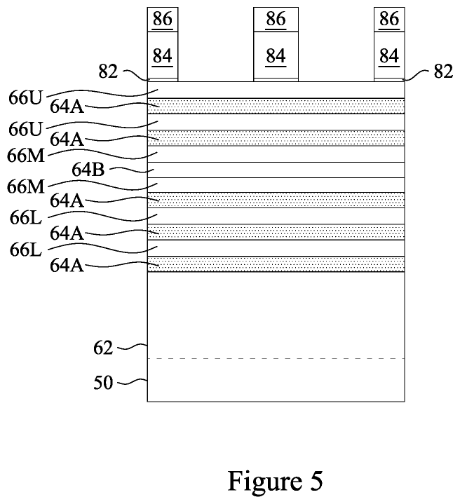

In FIG. 5, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise direction of respective semiconductor fins 62. The masks 86 can optionally be removed after patterning, such as by using any acceptable etching technique.

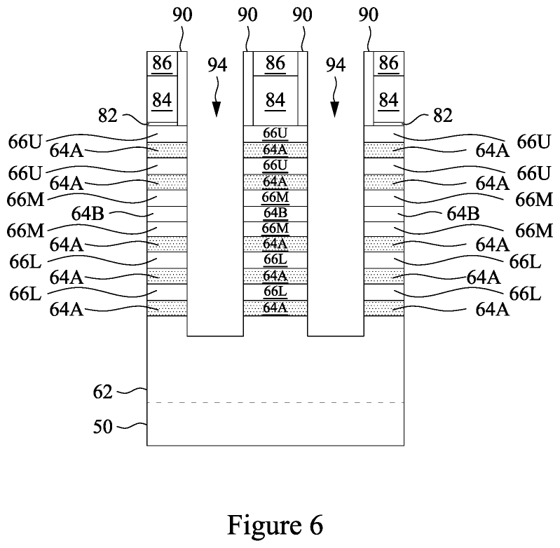

In FIG. 6, gate spacers 90 are formed over the nanostructures 64/66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, a wet etch, the like, or a combination thereof, may be performed to pattern the dielectric material(s). The etching may be anisotropic. The dielectric material(s), when etched, have portions left on the sidewalls of the dummy gates 84 (thus forming the gate spacers 90). As will be subsequently described in greater detail, the dielectric material(s), when etched, may also have portions left on the sidewalls of the semiconductor fins 62 and/or the nanostructures 64/66 (thus forming fin spacers 92, see FIG. 8C).

Further, implants for lightly doped source/drain (LDD) regions (not separately illustrated) may be performed. The LDD implants may be performed before the gate spacers 90 are formed. Appropriate type impurities may be implanted into the nanostructures 64/66 to a desired depth. The LDD regions may have a same conductivity type as a conductivity type of source/drain regions that will be subsequently formed adjacent the semiconductor nanostructures 66. Additionally, the LDD regions in the lower semiconductor nanostructures 66L may have a conductivity type opposite from a conductivity type of the LDD regions in the upper semiconductor nanostructures 66U. In some embodiments, the lower semiconductor nanostructures 66L have p-type LDD regions and the upper semiconductor nanostructures 66U have n-type LDD regions. In some embodiments, the lower semiconductor nanostructures 66L have n-type LDD regions and the upper semiconductor nanostructures 66U have p-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 10²⁰ atoms/cm³. An anneal may be used to repair implant damage and to activate the implanted impurities. In some embodiments, the grown materials of the nanostructures 64/66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

Source/drain recesses 94 are formed in the semiconductor fins 62, the nanostructures 64/66, and the substrate 50. Epitaxial source/drain regions will be subsequently formed in the source/drain recesses 94. The source/drain recesses 94 may extend through the nanostructures 64/66 and into the substrate 50. The semiconductor fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the semiconductor fins 62, the nanostructures 64/66, and the substrate 50 using anisotropic etching processes, such as RIE, NBE, or the like. The gate spacers 90 and the dummy gates 84 mask portions of the semiconductor fins 62, the nanostructures 64/66, and the substrate 50 during the etching processes used to form the source/drain recesses 94. A single etch process or multiple etch processes may be used to etch each layer of the nanostructures 64/66 and/or the semiconductor fins 62. Timed etch processes may be used to stop the etching of the source/drain recesses 94 after the source/drain recesses 94 reach a desired depth.

In FIG. 7, inner spacers 98 are formed on the sidewalls of the remaining portions of the first dummy nanostructures 64A. As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures. Additionally, the second dummy nanostructures 64B are replaced with isolation structures 100, which are between the middle semiconductor nanostructures 66M. The isolation structures 100 and the middle semiconductor nanostructures 66M will define the boundaries of the lower nanostructure-FETs and the upper nanostructure-FETs. The isolation structures 100 may have similar dimensions as the second dummy nanostructures 64B they replaced.

As an example to form the inner spacers 98 and the isolation structures 100, the sidewalls of the first dummy nanostructures 64A exposed by the source/drain recesses 94 are recessed to form sidewall recesses. Additionally, the second dummy nanostructures 64B are removed to form openings between the middle semiconductor nanostructures 66M, e.g., between the lower semiconductor nanostructures 66L (collectively) and the upper semiconductor nanostructures 66U (collectively). The sidewall recesses may be formed by recessing the sidewalls of the first dummy nanostructures 64A with any acceptable etch process. The etching is selective to the first dummy nanostructures 64A (e.g., selectively etches the material of the first dummy nanostructures 64A at a faster rate than the material of the semiconductor nanostructures 66). The etching may be isotropic. Although sidewalls of the first dummy nanostructures 64A are illustrated as being straight after the etching, the sidewalls may be concave or convex. The openings between the middle semiconductor nanostructures 66M may be formed by removing the second dummy nanostructures 64B with any acceptable etch process. The etching is selective to the second dummy nanostructures 64B (e.g., selectively etches the material of the second dummy nanostructures 64B at a faster rate than the material of the semiconductor nanostructures 66). The etching may be isotropic. The dummy gates 84 may adhere to and support the upper semiconductor nanostructures 66U so that the upper semiconductor nanostructures 66U do not collapse after the formation of the openings between the middle semiconductor nanostructures 66M. The middle semiconductor nanostructures 66M are exposed by the openings. In some embodiments, the etching process thins the middle semiconductor nanostructures 66M. Accordingly, the thickness of the middle semiconductor nanostructures 66M may be different (e.g., less than) the thickness of the lower semiconductor nanostructures 66L and the thickness of the upper semiconductor nanostructures 66U.

In some embodiments, the same etching process is used to recess the sidewalls of the first dummy nanostructures 64A and to remove the second dummy nanostructures 64B. For example, the second dummy nanostructures 64B may be completely removed without completely removing the first dummy nanostructures 64A, and the first dummy nanostructures 64A may be recessed without significantly recessing the semiconductor nanostructures 66. The etching process has selectivity among the materials of the first dummy nanostructures 64A, the second dummy nanostructures 64B, and the semiconductor nanostructures 66. Specifically, the etching process selectively etches the material of the first dummy nanostructures 64A at a faster rate than the material of the semiconductor nanostructures 66, and also selectively etches the material of the second dummy nanostructures 64B at a faster rate than the selectively etches the material of the first dummy nanostructures 64A. Thus, the etch rate of the first dummy nanostructures 64A is less than the etch rate of the second dummy nanostructures 64B and is greater than the etch rate of the semiconductor nanostructures 66.

An insulating material is then conformally formed in the source/drain recesses 94, the sidewall recesses, and the openings between the middle semiconductor nanostructures 66M, and subsequently etched. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses (thus forming the inner spacers 98) and has portions remaining in the openings between the middle semiconductor nanostructures 66M (thus forming the isolation structures 100).

Although outer sidewalls of the inner spacers 98 and the isolation structures 100 are illustrated as being flush with sidewalls of the semiconductor nanostructures 66, the outer sidewalls of the inner spacers 98 and the isolation structures 100 may extend beyond or be recessed from sidewalls of the semiconductor nanostructures 66. Thus, the inner spacers 98 and the isolation structures 100 may partially fill, completely fill, or overfill the sidewall recesses and the openings between the middle semiconductor nanostructures 66M, respectively. Moreover, although the sidewalls of the inner spacers 98 and the isolation structures 100 are illustrated as being straight, those sidewalls may be concave or convex.

Lower epitaxial source/drain regions 108L are then formed in the lower portions of the source/drain recesses 94. The lower epitaxial source/drain regions 108L only partially fill the source/drain recesses 94, such that the lower epitaxial source/drain regions 108L are in contact with the lower semiconductor nanostructures 66L and are not in contact with the upper semiconductor nanostructures 66U. The lower epitaxial source/drain regions 108L are formed in the source/drain recesses 94 such that each stack of the lower semiconductor nanostructures 66L is disposed between respective neighboring pairs of the lower epitaxial source/drain regions 108L. In some embodiments, the inner spacers 98 are used to separate the lower epitaxial source/drain regions 108L from the first dummy nanostructures 64A by an appropriate lateral distance so that the lower epitaxial source/drain regions 108L do not short out with subsequently formed gates of the resulting devices. The lower epitaxial source/drain regions 108L comprise one or more semiconductor material layers epitaxially grown in the lower portions of the source/drain recesses 94. The lower epitaxial source/drain regions 108L have a conductivity type that is suitable for the device type of the lower nanostructure-FETs. In some embodiments, the lower epitaxial source/drain regions 108L exert stress in the respective channel regions of the lower semiconductor nanostructures 66L, thereby improving performance.

In some embodiments, the lower nanostructure-FET is p-type (e.g., a PMOS transistor), and the lower epitaxial source/drain regions 108L are p-type source/drain regions. For example, p-type lower epitaxial source/drain regions 108L may comprise materials such as silicon germanium, boron-doped silicon germanium, boron-doped silicon, germanium, germanium tin, or the like. In some embodiments, p-type lower epitaxial source/drain regions 108L may include materials exerting a compressive strain on the lower semiconductor nanostructures 66L, which may include one or more of these example materials. In some embodiments, materials such as these may be used with lower semiconductor nanostructures 66L comprising silicon germanium. In other embodiments, the lower nanostructure-FET is n-type and/or the lower epitaxial source/drain regions 108L are n-type source/drain regions. The lower epitaxial source/drain regions 108L may have surfaces raised from respective upper surfaces of the lower semiconductor nanostructures 66L and may have facets. Other materials or combinations of materials are possible.

The lower epitaxial source/drain regions 108L may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the lower epitaxial source/drain regions 108L are in situ doped during growth.

As a result of the epitaxy processes used to form the lower source/drain regions 108L, upper surfaces of the lower source/drain regions 108L have facets which expand laterally outward beyond sidewalls of the nanostructures 64/66. In some embodiments, adjacent lower source/drain regions 108L remain separated after the epitaxy process is completed as illustrated by FIG. 14C. In other embodiments, these facets cause adjacent lower source/drain regions 108L of a same nanostructure-FET to merge (not separately illustrated). In some embodiments, fin spacers 92 (see FIG. 8C) are formed on a top surface of the isolation regions 70, thereby blocking the epitaxial growth. In some other embodiments, the fin spacers 92 may cover portions of the sidewalls of the nanostructures 64, 66 and/or the semiconductor fins 62, further blocking the epitaxial growth. In another embodiment, the spacer etch used to form the gate spacers 90 is adjusted to not form the fin spacers 92, so as to allow the lower epitaxial source/drain regions 108L to extend to the surface of the isolation regions 70.

A first ILD 114 is then formed over the lower epitaxial source/drain regions 108L. The first ILD 114 may be formed of a dielectric material, which may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

In some embodiments, a first contact etch stop layer (CESL) 112 is formed between the first ILD 114 and the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like.

The first CESL 112 and/or the first ILD 114 may be formed by depositing a material for the first CESL 112 and depositing a material for the first ILD 114, followed by an etch-back process. In some embodiments, the first ILD 114 is initially etched, leaving the first CESL 112 unetched. An anisotropic etching process is then performed to remove the portions of the first CESL 112 that are higher than the first ILD 114. After the recessing, sidewalls of the upper semiconductor nanostructures 66U are exposed.

In FIGS. 8A-8C, upper epitaxial source/drain regions 108U are then formed in the upper portions of the source/drain recesses 94. In some embodiments, the upper epitaxial source/drain regions 108U are formed by epitaxially growing source/drain material, implanting dopants into the source/drain material, and then performing a rapid thermal process to recrystallize the source/drain material and activate the implanted dopants, a process which is described in greater detail below. The upper epitaxial source/drain regions 108U only partially fill the source/drain recesses 94, such that the upper epitaxial source/drain regions 108U are in contact with the upper semiconductor nanostructures 66U and are not in contact with the lower semiconductor nanostructures 66L.

The source/drain recesses 94 contain the upper epitaxial source/drain regions 108U, the first ILD 114, the first CESL 112, and the lower epitaxial source/drain regions 108L. The first ILD 114 and the first CESL 112 are between the upper epitaxial source/drain regions 108U and the lower epitaxial source/drain regions 108L. The lower epitaxial source/drain regions 108L are for lower nanostructure-FETs of the CFETs, and the upper epitaxial source/drain regions 108U are for upper nanostructure-FETs of the CFETs. The first ILD 114 and the first CESL 112 provide isolation between the upper epitaxial source/drain regions 108U and the lower epitaxial source/drain regions 108L regions to prevent shorting of the lower and upper nanostructure-FETs.

The upper epitaxial source/drain regions 108U are formed in the source/drain recesses 94 such that each stack of the upper semiconductor nanostructures 66U is disposed between respective neighboring pairs of the upper epitaxial source/drain regions 108U. In some embodiments, the inner spacers 98 are used to separate the upper epitaxial source/drain regions 108U from the first dummy nanostructures 64A by an appropriate lateral distance so that the upper epitaxial source/drain regions 108U do not short out with subsequently formed gates of the resulting devices.

The upper epitaxial source/drain regions 108U are epitaxially grown in the upper portions of the source/drain recesses 94. For example, the upper source/drain regions 108U may be grown laterally from exposed sidewalls of the upper semiconductor nanostructures 66U. As a result of the epitaxy processes used to form the upper source/drain regions 108U, upper surfaces of the upper source/drain regions 108U have facets which expand laterally outward beyond sidewalls of the nanostructures 64/66. In some embodiments, adjacent upper source/drain regions 108U remain separated after the epitaxy process is completed. In other embodiments, as the upper source/drain regions 108U grow in the source/drain recesses 94, the facets cause adjacent upper source/drain regions 108U of a same nanostructure-FET to merge (not separately illustrated). The upper epitaxial source/drain regions 108U may have surfaces raised from respective upper surfaces of the upper semiconductor nanostructures 66U. The upper source/drain regions 108U may comprise one or more semiconductor material layers.

The upper epitaxial source/drain regions 108U have a conductivity type that is suitable for the device type of the upper nanostructure-FETs. The conductivity type of the upper epitaxial source/drain regions 108U may be opposite the conductivity type of the lower epitaxial source/drain regions 108L. Put another way, the upper epitaxial source/drain regions 108U may be oppositely doped from the lower epitaxial source/drain regions 108L. For example, in embodiments in which the lower epitaxial source/drain regions 108L are p-type, the upper epitaxial source/drain regions 108U may be n-type. In some embodiments, the upper epitaxial source/drain regions 108U exert stress in the respective channel regions of the upper semiconductor nanostructures 66U, thereby improving performance.

In some embodiments, the upper nanostructure-FET is n-type (e.g., a NMOS transistor), and the upper epitaxial source/drain regions 108U are n-type source/drain regions. For example, the upper epitaxial source/drain regions 108U may comprise materials such as silicon, carbon-doped silicon, phosphorous-doped and carbon-doped silicon, silicon phosphide, silicon arsenide, or the like. The upper epitaxial source/drain regions 108U may be implanted with dopants to form source/drain regions, described in greater detail below. In some embodiments, the upper epitaxial source/drain regions 108U are in situ doped during growth.

In some embodiments, n-type upper epitaxial source/drain regions 108U may include materials exerting a tensile strain on the upper semiconductor nanostructures 66U, which may include one or more of these example materials. In some embodiments, materials such as these may be used with upper semiconductor nanostructures 66U comprising silicon. In other embodiments, the upper epitaxial source/drain regions 108U are p-type source/drain regions and/or the lower epitaxial source/drain regions 108L are n-type source/drain regions.

In some embodiments, the upper epitaxial source/drain regions 108U are doped using an amorphizing implantation process to implant dopants into the epitaxial material followed by a rapid thermal process to recrystallize the epitaxial material and activate the implanted dopants. Forming the upper epitaxial source/drain regions 108U in this manner can allow for doping and activation of dopants within the upper epitaxial source/drain regions 108U without subjecting the lower epitaxial source/drain regions 108L or the upper epitaxial source/drain regions 108U to thermal conditions that cause stress relaxation that reduces device performance. Activating the dopants in the upper epitaxial source/drain regions 108U can reduce bulk resistance and contact resistance of the upper epitaxial source/drain regions 108U, and thus improve device performance.

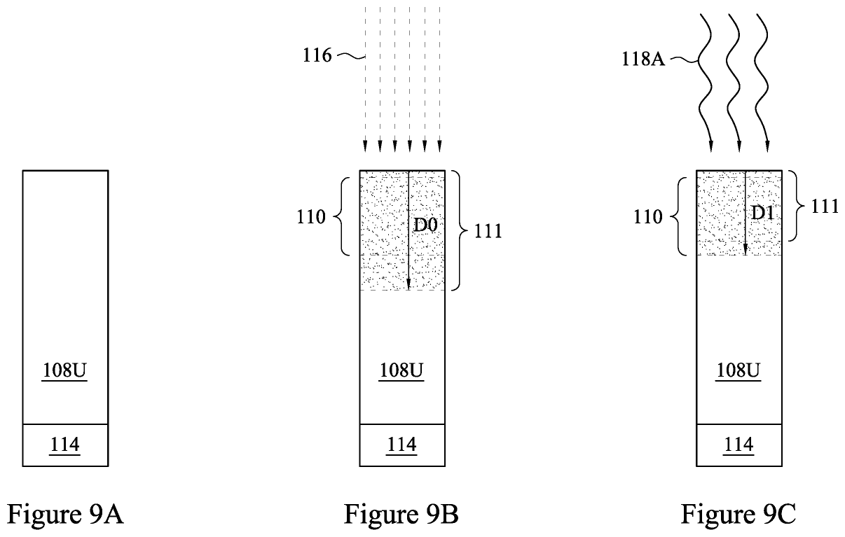

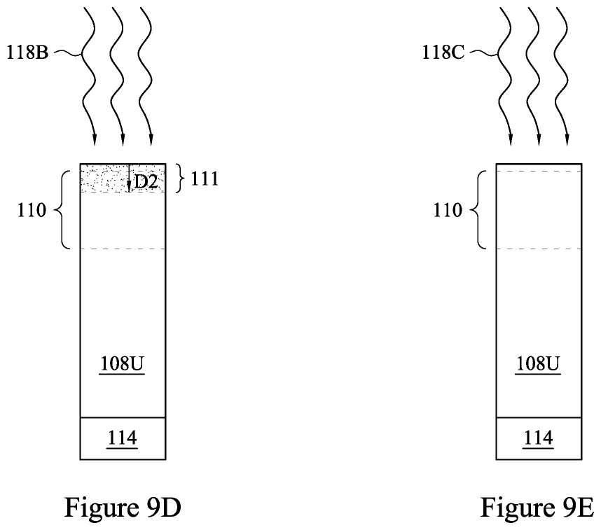

As an illustrative example, FIGS. 9A-9E illustrate intermediate steps of an example doping and doping activation process for the upper epitaxial source/drain regions 108U, in accordance with some embodiments. FIGS. 9A-9E illustrate cross-sectional views of a portion of an upper epitaxial source/drain region 108U, which may be similar to the upper epitaxial source/drain regions 108U described for FIGS. 8A-8C. For example, the upper epitaxial source/drain region 108U formed in FIGS. 9A-9E may be may be an n-type source/drain region formed of doped silicon, though other materials are possible.

FIG. 9A shows the upper epitaxial source/drain region 108U prior to dopant implantation, in accordance with some embodiments. The upper epitaxial source/drain region 108U may be grown epitaxially using materials described above, such as silicon or another material. The upper epitaxial source/drain region 108U of FIG. 9A may be undoped or may be in situ doped during growth. Accordingly, the upper epitaxial source/drain region 108U of FIG. 9A may be substantially crystalline.

In FIG. 9B, an amorphizing implantation process 116 is performed on the upper epitaxial source/drain region 108U, in accordance with some embodiments. The amorphizing implantation process 116 implants dopants (e.g., impurities, ions, etc.)

into the upper epitaxial source/drain region 108U and also at least partially amorphizes the upper epitaxial source/drain region 108U. For the example shown in FIG. 9B, the amorphizing implantation process 116 amorphizes crystalline material of the upper epitaxial source/drain region 108U into amorphous (or relatively amorphous) material, forming an amorphous region 111 within the upper epitaxial source/drain region 108U. In some cases, because the amorphizing implantation process 116 is performed before the upper epitaxial source/drain region 108U has been amorphized, the amorphizing implantation process 116 may be considered a “pre-amorphous implant.” Additionally, the amorphizing implantation process 116 implants dopants into the upper epitaxial source/drain region 108U to form a doped region 110, which may be at least partially within the amorphous region 111. The amorphous region 111 and doped region 110 shown in FIG. 9B are illustrative examples, and amorphous regions 111 and/or doped regions 110 may have different locations, sizes, or depths within the upper epitaxial source/drain region 108U. Additionally, the boundaries of the amorphous region 111 and doped region 110 are shown as distinct (e.g., abrupt), but in some cases the boundaries of these regions may be gradual (e.g., gradients). Amorphizing the upper epitaxial source/drain region 108U using the amorphizing implantation process 116 as described herein allows the subsequently performed rapid thermal process(es) 118 to activate dopants while recrystallizing the amorphous material, described in greater detail below.

In some embodiments, the parameters of the amorphizing implantation process 116 are controlled to implant dopants in a manner that amorphizes the crystalline material of the upper epitaxial source/drain regions 108U to form the amorphous region 111. For example, in some cases, a lower implantation process temperature may promote amorphization of the target material. Accordingly, in some embodiments, the amorphizing implantation process 116 may be performed using a low process temperature, such as a process temperature in the range of about −100° C. to about 28° C., though other temperatures are possible. In some embodiments, the amorphizing implantation process 116 may have an implantation energy in the range of about 1 keV to about 8 keV, though other energies are possible. In some embodiments, the amorphizing implantation process 116 may implant dopants at a dose in the range of about 2×10¹⁵ atoms/cm² to about 1.4×10¹⁶ atoms/cm², though other doses are possible.

In some embodiments, the initial amorphous region 111 may have a depth D0 from a top surface of the upper epitaxial source/drain region 108U that is in the range of about 5 nm to about 15 nm. The depth D0 may be between about 10% and about 30% of a total height (e.g., top surface to bottom surface) of the upper epitaxial source/drain region 108U. Other depths are possible. Below the amorphous region 111, the material of the upper epitaxial source/drain region 108U is substantially crystalline. The transition from the substantially amorphous material of the amorphous region 111 to the underlying substantially crystalline material may be abrupt, irregular, or gradual. In some cases, the depth D0 may be measured from a top surface of the upper epitaxial source/drain region 108U to a depth at which the upper epitaxial source/drain region 108U is substantially crystalline. In some cases, the depth D0 may be measured from a top surface of the upper epitaxial source/drain region 108U to a depth at which the upper epitaxial source/drain region 108U is about half crystalline material and about half amorphous material. In some embodiments, the depth D0 of the amorphous region 111 may be controlled by controlling parameters of the amorphizing implantation process 116, such as the temperature or energy.

The amorphizing implantation process 116 may implant suitable n-type and/or p-type impurities for source/drain regions, which may be any of the impurities previously discussed. As an example, for embodiments in which the upper epitaxial source/drain regions 108U are n-type, the implanted impurities may comprise arsenic, phosphorus, diphosphorus (e.g., P₂), or the like. In some cases, implanting relatively large species such as arsenic or diphosphorus can promote amorphization, particularly at relatively low process temperatures. Other impurities are possible.

In this manner, the amorphizing implantation process 116 forms doped regions 110 within the upper epitaxial source/drain regions 108U. The doped region 110 may be fully within the amorphous region 111, as shown in FIG. 9B, though in other cases the doped region 110 may extend into the crystalline region of the upper epitaxial source/drain region 108U. The doped regions 110 may have an impurity concentration in the range of about 10¹⁹ atoms/cm³ to about 10²¹ atoms/cm³, though other concentrations are possible. The location, depth, height, boundaries, or concentration profile of the doped region 110 may be controlled by controlling parameters of the amorphizing implantation process 116, such as temperature, energy, dose, or the like. The boundaries of the doped region 110 may be abrupt, irregular, or gradual. For example, the impurity concentration profile near a boundary of the doped region 110 may be a step or a gradient. Accordingly, in some cases, a nonzero concentration of implanted impurities may be present in regions outside of the example doped region 110 indicated in FIGS. 9B-9E. In some cases, the upper boundary of a doped region 110 may be a top surface of the upper epitaxial source/drain region 108U.

After performing the amorphizing implantation process 116, a rapid thermal process 118 may be performed one or more times, in accordance with some embodiments. The rapid thermal process 118 is an annealing process or other heating process that heats the structure for a brief duration of time, described in greater detail below. In FIG. 9C, a first rapid thermal process 118A is performed, in FIG. 9D, a second rapid thermal process 118B is performed, and in FIG. 9C, a third rapid thermal process 118C is performed. More or fewer rapid thermal processes 118 may be performed in other embodiments. The rapid thermal process(es) 118 are performed to recrystallize the amorphous region 110 into crystalline material that incorporates the implanted impurities of the doped region 110. For example, the crystalline material may incorporate impurities on lattice sites. In this manner, the implanted impurities may be “activated” within the upper epitaxial source/drain region 108U, which can improve device performance. In some cases, the rapid thermal process 118 also reduces or eliminates implant damage from the upper epitaxial source/drain region 108U. In some cases, the use of rapid thermal process 118 as described herein allows for the activation of dopants within the upper epitaxial source/drain region 108U with reduced stress relaxation of the lower epitaxial source/drain region 108L and/or the upper epitaxial source/drain region 108U, described in greater detail below.

In some embodiments, the rapid thermal process 118 heats the structure for a brief duration of time, such as a duration in the range of about 1 ms to about 10 ms. For example, in some embodiments, the rapid thermal process 118 may heat the structure for a duration of time that is less than about 5 ms. The duration of time may be longer or shorter than these examples in other embodiments. The rapid thermal process 118 may include a heating temperature in the range of about 800° C. to about 1250° C., though other temperatures are possible. In some embodiments, the rapid thermal process 118 may heat the structure to a temperature in the range of about 800° C. to about 1250° C., though other temperatures are possible. In some embodiments, the rapid thermal process 118 may heat the structure to a temperature less than about 1250° C. In some cases, the brief time duration of the rapid thermal process 118 subjects the structure to lower temperatures and/or less thermal stress, which can reduce epitaxial material relaxation (described in greater detail below). For embodiments in which multiple rapid thermal processes 118 are performed, the various rapid thermal processes 118 may have similar parameters (e.g., temperature, duration, rise or fall rate, etc.) or different parameters. For embodiments in which multiple rapid thermal processes 118 are performed, each rapid thermal process 118 performed may be considered a separate process. For example, in some embodiments, the structure may be allowed to partially or fully cool before performing a subsequent rapid thermal process 118. The rapid thermal process(es) 118 may be performed using a rapid thermal anneal (RTA), a laser anneal, or the like.

In some embodiments, each rapid thermal process 118 causes a lower portion of the amorphous material of the amorphous region 111 to recrystallize into a crystalline material. The recrystallization of the amorphous region 111 may be a solid phase epitaxial regrowth process that is “seeded” by the underlying crystalline material. For example, portions of the amorphous region 111 near the transition between the amorphous region 111 and the underlying crystalline region may recrystallize. Thus, the transition between amorphous material and crystalline material moves toward a top surface of the upper epitaxial source/drain region 108U. In other words, a rapid thermal process 118 increases the relative height of the crystalline region and decreases the relative height of the overlying amorphous region 111. This is shown in FIGS. 9B-9E, as each subsequently performed rapid thermal process 118A-C decreases the depth of the amorphous region 111 from the initial depth D0, described in greater detail below. In some embodiments, the thickness of the portion of the amorphous region 111 that recrystallizes during a single rapid thermal process 118 may be in the range of about 5 nm to about 15 nm, though other sizes of recrystallized amorphous region 111 are possible. The thickness of the amorphous region 111 that recrystallizes during a rapid thermal process 118 may be controlled by controlling the parameters of the rapid thermal process 118, such as the temperature or duration. In some cases, a rapid thermal process 118 may change the boundaries or the concentration profile of the doped region 110.

In FIG. 9C, a first rapid thermal process 118A is performed on the upper epitaxial source/drain region 108U, in accordance with some embodiments. As shown in FIG. 9C, the first rapid thermal process 118A causes a portion of the amorphous region 111 to recrystallize such that the depth of the amorphous region 111 is reduced from its initial depth D0 to a smaller depth D1. The difference between D0 and D1 (e.g., Do-D1) corresponds to a thickness of the region that was recrystallized by the first rapid thermal process 118A. FIG. 9C shows that, after performing the first rapid thermal process 118A, a bottom boundary of the amorphous region 111 is above a bottom boundary of the doped region 110, but in other embodiments the doped region 110 may still be within the amorphous region 111 after performing the first rapid thermal process 118A. In other embodiments, the first rapid thermal process 118A recrystallizes a larger or smaller portion of the amorphous region 111. In other embodiments, the first rapid thermal process 118A recrystallizes all of the amorphous region 111.

In FIG. 9D, a second rapid thermal process 118B is performed on the upper epitaxial source/drain region 108U, in accordance with some embodiments. The second rapid thermal process 118B may have parameters that are similar to or different from those of the first rapid thermal process 118A. As shown in FIG. 9D, the second rapid thermal process 118B causes a portion of the amorphous region 111 to recrystallize such that the depth of the amorphous region 111 is reduced from depth D1 to a smaller depth D2. The difference between D1 and D2 (e.g., D1-D2) corresponds to a thickness of the region that was recrystallized by the second rapid thermal process 118B. In other embodiments, the second rapid thermal process 118B recrystallizes a larger or smaller portion of the amorphous region 111. In other embodiments, the second rapid thermal process 118B recrystallizes all of the remaining amorphous region 111.

In FIG. 9E, a third rapid thermal process 118C is performed on the upper epitaxial source/drain region 108U, in accordance with some embodiments. The third rapid thermal process 118C may have parameters that are similar to or different from those of the first rapid thermal process 118A and/or the second rapid thermal process 118B. As shown in FIG. 18E, the third rapid thermal process 118C causes the remaining portion of the amorphous region 111 to recrystallize such that the upper epitaxial source/drain region 108U becomes fully or substantially crystalline. The depth D2 corresponds to a thickness of the region that was recrystallized by the third rapid thermal process 118C. In other embodiments, the third rapid thermal process 118C does not fully recrystallize the remaining amorphous region 111. FIGS. 9A-9E show three rapid thermal processes 118 being performed to recrystallize the amorphous region 111, but in other embodiments more or fewer rapid thermal processes 118 may be performed.

Recrystallizing a doped amorphous material to form source/drain regions as described herein can reduce the thermal stress experienced by the structure and improve device performance. In some cases, heating a structure to temperatures sufficient to thermally activate implanted dopants in crystalline material can cause relaxation of stressed epitaxial material. For example, high enough temperatures can cause the relaxation of epitaxial source/drain material that imparts channel stress, which can reduce device performance. In this manner, the manufacturing process may have a “thermal budget” that may be at least partially determined by avoiding temperatures high enough to cause epitaxial material relaxation. By recrystallizing the upper epitaxial source/drain regions 108U using rapid thermal processes 118 as described herein, dopants in the upper epitaxial source/drain regions 108U may be activated using relatively lower temperatures that have a reduce risk of causing relaxation in the lower epitaxial source/drain regions 108L and/or in the upper epitaxial source/drain regions 108U. In other words, the techniques described herein can allow for dopant activation with little or no epitaxial relaxation. This can improve device performance while avoiding thermal processing conditions that may reduce device performance. This can also allow for greater parameter flexibility in subsequent thermal processes.

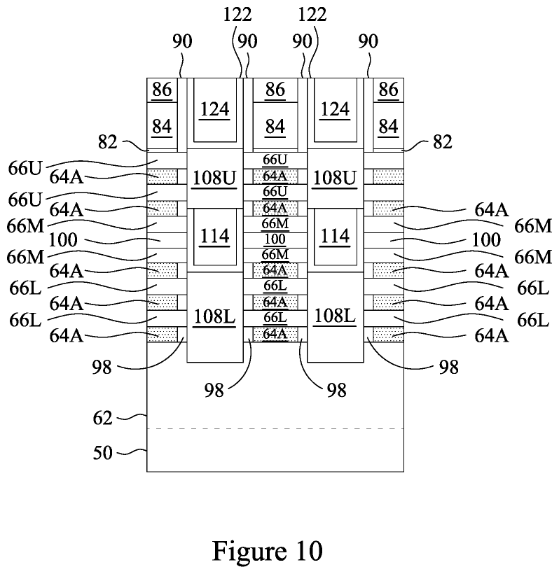

In FIG. 10, a second ILD 124 is deposited over the upper epitaxial source/drain regions 108U. The second ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

A second CESL 122 may be formed between the second ILD 124 and the upper epitaxial source/drain regions 108U. The second CESL 122 may be formed of a dielectric material having a high etching selectivity to the dielectric material of the second ILD 124, such as silicon nitride, silicon oxide, silicon oxynitride, or the like, which may be formed by any suitable deposition process, such as CVD, ALD, or the like.

The second CESL 122 and/or the second ILD 124 may be formed by depositing a material for the second CESL 122 and depositing a material for the second ILD 124. A removal process is then performed to level the top surfaces of the second ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 124, the gate spacers 90, and the masks 86 (if present) or the dummy gates 84 are substantially coplanar (within process variations). Accordingly, the top surfaces of the masks 86 (if present) or the dummy gates 84 are exposed through the second ILD 124. In the illustrated embodiment, the masks 86 remain after the removal process. In other embodiments, the masks 86 are removed such that the top surfaces of the dummy gates 84 are exposed through the second ILD 124.

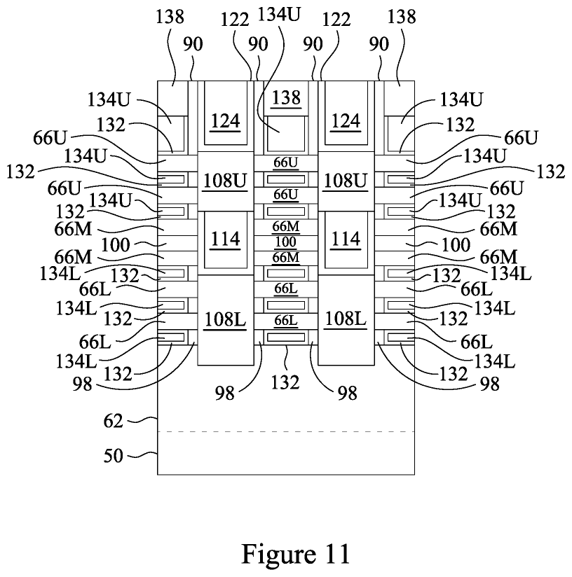

In FIG. 11, the dummy gates 84 are removed in one or more etching steps, so that recesses are formed between the gate spacers 90. Portions of the dummy dielectrics 82 in the recesses are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 124, the isolation structures 100, the inner spacers 98, and the gate spacers 90. Each recess between the gate spacers 90 exposes and/or overlies portions of the semiconductor nanostructures 66 which act as the channel regions in the resulting devices. The portions of the semiconductor nanostructures 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings between the semiconductor nanostructures 66.

Next, gate dielectrics 132 and gate electrodes 134 (including lower gate electrodes 134L and upper gate electrodes 134U) are formed for replacement gates. Each respective pair of a gate dielectric 132 and a gate electrode 134 (including an upper gate electrode 134U and/or a lower gate electrode 134L) may be collectively referred to as a “gate structure.” Each gate structure extends along at least three sides (e.g., a top surface, a sidewall, and a bottom surface) of a channel region of a semiconductor nanostructure 66. The gate structures may also extend along sidewalls and/or a top surface of a semiconductor fin 62.

The gate dielectrics 132 include one or more gate dielectric layer(s) disposed around the lower semiconductor nanostructures 66L, the upper semiconductor nanostructures 66U, and the isolation structures 100. Specifically, the gate dielectrics 132 are disposed on the sidewalls and/or the top surfaces of the semiconductor fins 62; on the top surfaces, the sidewalls, and the bottom surfaces of the semiconductor nanostructures 66; on the sidewalls of the inner spacers 98; and on the sidewalls of the gate spacers 90. The gate dielectrics 132 wrap around at least three sides of the semiconductor nanostructures 66. The gate dielectrics 132 may be formed of an oxide such as silicon oxide or a metal oxide, a silicate such as a metal silicate, combinations thereof, multi-layers thereof, or the like. Additionally or alternatively, the gate dielectrics 132 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 132 may be formed by molecular-beam deposition (MBD), ALD, PECVD, or the like. Although single-layered gate dielectrics 132 are illustrated, the gate dielectrics 132 may include any number of interfacial layers and any number of main layers. For example, the gate dielectrics 132 may include an interfacial layer and an overlying high-k dielectric layer.

The lower gate electrodes 134L include one or more gate electrode layer(s) disposed over the gate dielectrics 132 and around the lower semiconductor nanostructures 66L. The lower gate electrodes 134L are disposed in the lower portions of the recesses between the gate spacers 90 and in the openings between the lower semiconductor nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of material(s) that are suitable for the device type of the lower nanostructure-FETs. In some embodiments, the lower gate electrodes 134L include an n-type work function tuning layer, which may be formed of titanium aluminum, titanium aluminum carbide, tantalum aluminum, tantalum carbide, combinations thereof, or the like. In some embodiments, the lower gate electrodes 134L include a p-type work function tuning layer, which may be formed of titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The upper gate electrodes 134U include one or more gate electrode layer(s) disposed over the gate dielectrics 132 and around the upper semiconductor nanostructures 66U. The upper gate electrodes 134U are disposed in the upper portions of the recesses between the gate spacers 90 and in the openings between the upper semiconductor nanostructures 66U. The upper gate electrodes 134U may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the upper gate electrodes 134U may include any number of work function tuning layers, any number of barrier layers, any number of glue layers, and a fill material.

The upper gate electrodes 134U are formed of material(s) that are suitable for the device type of the upper nanostructure-FETs. For example, the upper gate electrodes 134U may include one or more work function tuning layer(s) formed of work function tuning metal(s) that are suitable for the device type of the upper nanostructure-FETs. In some embodiments, the upper gate electrodes 134U include an n-type work function tuning layer, which may be formed of an n-type work function tuning metal such as titanium aluminum, titanium aluminum carbide, tantalum aluminum, tantalum carbide, combinations thereof, or the like. In some embodiments, the upper gate electrodes 134U include a p-type work function tuning layer, which may be formed of a p-type work function tuning metal such as titanium nitride, tantalum nitride, combinations thereof, or the like. The work function tuning metal(s) of the upper gate electrodes 134U may be different than the work function tuning metal(s) of the lower gate electrodes 134L. Additionally or alternatively, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L.

In some embodiments, isolation layers (not separately illustrated) are formed between the lower gate electrodes 134L and the upper gate electrodes 134U. The isolation layers act as isolation features between the lower gate electrodes 134L and the upper gate electrodes 134U. The isolation layers may be formed of a dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. In embodiments where the isolation layers are formed, the isolation layers and the isolation structures 100 together isolate the upper gate electrodes 134U from the lower gate electrodes 134L. Accordingly, an upper nanostructure-FET may be isolated from a lower nanostructure-FET by a combination of an isolation structure 100 and an isolation layer. In some embodiments where the isolation layers are omitted, an upper nanostructure-FET may be coupled to a lower nanostructure-FET. When the isolation layers are omitted, the lower gate electrodes 134L may be physically and electrically coupled to the upper gate electrodes 134U.

A removal process is performed to remove the excess portions of the upper gate electrode layer(s), which excess portions are over the top surfaces of the gate spacers 90 and the second ILD 124, such that the upper gate electrode layer(s) remain in the openings between the upper semiconductor nanostructures 66U. In some embodiments, a planarization process such as a chemical mechanical polish (CMP), an etch-back process, combinations thereof, or the like may be utilized. The gate dielectric layer(s), after the removal process, have portions remaining in the recesses between the gate spacers 90 and the openings between the semiconductor nanostructures 66 (thus forming the gate dielectrics 132). The lower gate electrode layer(s), after the removal process, have portions left in the lower portions of the recesses between the gate spacers 90 and in the openings between the lower semiconductor nanostructures 66L (thus forming the lower gate electrodes 134L). The upper gate electrode layer(s), after the removal process, have portions left in the upper portions of the recesses between the gate spacers 90 and in the openings between the upper semiconductor nanostructures 66U (thus forming the upper gate electrodes 134U). When a planarization process is utilized, the top surfaces of the gate spacers 90, the second ILD 124, the gate dielectrics 132, and the upper gate electrodes 134U are coplanar (within process variations) after the planarization process.

In some embodiments, gate masks 138 are formed over the gate structures (including the gate dielectrics 132 and the gate electrodes 134). The gate masks 138 may (or may not) also be formed over the gate spacers 90. Gate contacts may be subsequently formed through the gate masks 138 to contact the top surfaces of the upper gate electrodes 134U. As an example to form the gate masks 138, the gate structures may be recessed using any acceptable etching process. In some embodiments (not separately illustrated), the gate spacers 90 are also recessed. One or more dielectric material(s) are then conformally deposited in the recesses. The dielectric material(s) may also be deposited on the top surfaces of the second ILD 124 and the gate spacers 90. Acceptable dielectric materials may include silicon nitride, silicon carbonitride, silicon oxynitride, silicon oxycarbonitride, or the like, which may be formed by a conformal deposition process such as chemical vapor deposition (CVD), atomic layer deposition (ALD), plasma-enhanced atomic layer deposition (PEALD), or the like. Other dielectric materials formed by any acceptable process may be used. A removal process is performed to remove the excess portions of the dielectric material(s), which excess portions are over the top surfaces of the second ILD 124 and the gate spacers 90, thereby forming the gate masks 138. In some embodiments, a planarization process such as a chemical mechanical polish (CMP), an etch-back process, combinations thereof, or the like is utilized. The dielectric material(s), when planarized, have portions left in the recesses (thus forming the gate masks 138). After the planarization process, the top surfaces of the gate spacers 90, the second ILD 124, and the gate masks 138 are substantially coplanar (within process variations).

In FIGS. 12A-12C, upper source/drain contacts 144 are formed for the source/drain regions 108. The upper source/drain contacts 144 may be physically and electrically coupled to the upper epitaxial source/drain regions 108U. As an example to form the upper source/drain contacts 144, openings for the upper source/drain contacts 144 are formed through the second ILD 124 and the second CESL 122. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90 and the second ILD 124. The remaining liner and conductive material form the upper source/drain contacts 144 in the openings. In some embodiments, a planarization process such as a chemical mechanical polish (CMP), an etch-back process, combinations thereof, or the like is utilized. After the planarization process, the top surfaces of the gate spacers 90, the second ILD 124, the gate masks 138, and the upper source/drain contacts 144 are substantially coplanar (within process variations).

Optionally, metal-semiconductor alloy regions 142 are formed at the interfaces between the upper epitaxial source/drain regions 108U and the upper source/drain contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the upper source/drain contacts 144 by depositing a metal in the openings for the upper source/drain contacts 144 and then performing a thermal anneal process. The metal can be any metal capable of reacting with the semiconductor materials (e.g., silicon, silicon-germanium, germanium, etc.) of the upper epitaxial source/drain regions 108U to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the upper source/drain contacts 144, such as from surfaces of the metal-semiconductor alloy regions 142. The material(s) of the upper source/drain contacts 144 can then be formed on the metal-semiconductor alloy regions 142.

In the illustrated embodiment, the upper source/drain contacts 144 are coupled to the upper epitaxial source/drain regions 108U. In another embodiment (not separately illustrated), some of the upper source/drain contacts 144 are shared source/drain contacts that are coupled to both the upper epitaxial source/drain regions 108U and the lower epitaxial source/drain regions 108L. For example, a shared source/drain contact may be formed through an upper epitaxial source/drain region 108U, the first ILD 114, and the first CESL 112 to be coupled to a lower epitaxial source/drain region 108L. When forming such a shared source/drain contact, the opening for the shared source/drain contact may also be formed through an upper epitaxial source/drain region 108U, the first ILD 114, and the first CESL 112; additionally, a metal-semiconductor alloy region 142 may be formed on a sidewall of the upper epitaxial source/drain region 108U.

Further in FIGS. 12A-12C, a third ILD 154 is deposited over the gate spacers 90, the second ILD 124, the gate masks 138, and the upper source/drain contacts 144. In some embodiments, the third ILD 154 is a flowable film formed by a flowable CVD method, which is subsequently cured. In some embodiments, the third ILD 154 is formed of a dielectric material such as PSG, BSG, BPSG, USG, or the like, which may be deposited by any suitable method, such as CVD, PECVD, or the like.

In some embodiments, an etch stop layer (ESL) 152 is formed between the third ILD 154 and the gate spacers 90, the second ILD 124, the gate masks 138, and the upper source/drain contacts 144. The ESL 152 may include a dielectric material having a high etching selectivity to the dielectric material of the third ILD 154, such as silicon nitride, silicon oxide, silicon oxynitride, or the like.

Upper gate contacts 156 and upper source/drain vias 158 are formed through the third ILD 154 to contact, respectively, the upper gate electrodes 134U and the upper source/drain contacts 144. The upper gate contacts 156 are also formed through the gate masks 138 (if present). The upper gate contacts 156 may be physically and electrically coupled to the upper gate electrodes 134U. The upper source/drain vias 158 may be physically and electrically coupled to the upper source/drain contacts 144.

As an example to form the upper gate contacts 156 and the upper source/drain vias 158, openings for the upper gate contacts 156 and the upper source/drain vias 158 are formed through the third ILD 154 and the ESL 152. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 154. The remaining liner and conductive material form the upper gate contacts 156 and the upper source/drain vias 158 in the openings. The upper gate contacts 156 and the upper source/drain vias 158 may be formed in distinct processes, or may be formed in the same process. Although shown as being formed in the same cross-section, it should be appreciated that each of the upper gate contacts 156 and the upper source/drain vias 158 may be formed in different cross-sections, which may avoid shorting of the contacts.

The active devices as illustrated are collectively referred to as a device layer 160. In some embodiments, contacts to the lower gate electrodes 134L and/or the lower epitaxial source/drain regions 108L may be made through a backside of the device layer 160 (e.g., a side opposite to the upper source/drain contacts 144).

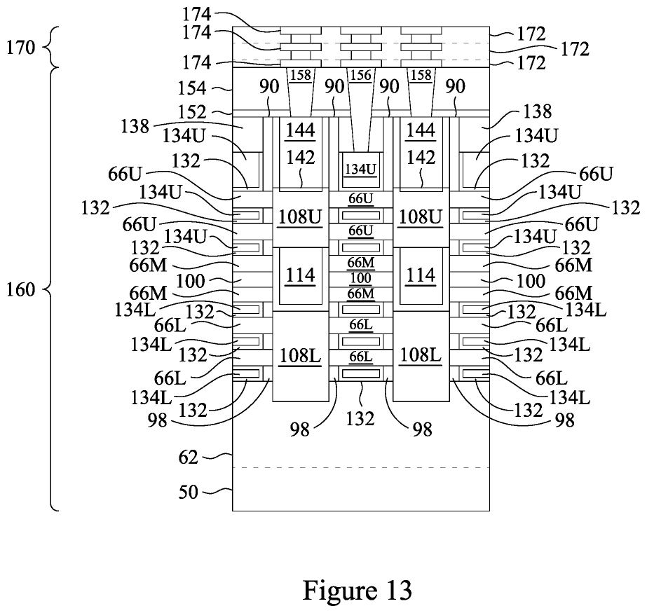

In FIG. 13, a front-side interconnect structure 170 is formed on the device layer 160, e.g., over the third ILD 154. The front-side interconnect structure 170 is referred to as a front-side interconnect structure because it is formed at a front-side of the device layer 160 (e.g., a side of the substrate 50 on which the devices are formed). The front-side interconnect structure 170 includes dielectric layers 172 and layers of conductive features 174 in the dielectric layers 172. The dielectric layers 172 may be formed of a suitable dielectric material, such as silicon oxide or the like. The conductive features 174 may include conductive lines and vias. The conductive vias may extend through respective ones of the dielectric layers 172 to provide vertical connections between layers of conductive lines. The conductive features 174 may be formed by a suitable process, such as a damascene process or the like. The front-side interconnect structure 170 includes any desired number of layers of the conductive features 174. The conductive features 174 are connected to features of the underlying devices (e.g., the upper gate electrodes 134U and the upper epitaxial source/drain regions 108U) through the upper gate contacts 156 and the source/drain vias 158 to form functional circuits. In other words, the conductive features 174 interconnect the upper nanostructure-FETs of the device layer 160.

Embodiments may achieve advantages. Techniques described herein allow for dopant activation of the upper epitaxial source/drain regions of a CFET without adversely affecting the performance of the lower epitaxial source/drain regions. Forming the upper epitaxial source/drain regions by forming amorphous doped portions of the upper source/drain regions and then performing rapid thermal processes to recrystallize the amorphous doped portions, as described herein, allows the dopants in the amorphous doped portions to be activated with a reduced risk of causing stress relaxation in the lower epitaxial source/drain regions. In some cases, the rapid nature of the rapid thermal processes used to recrystallize the amorphous doped portions does not heat the lower epitaxial source/drain regions enough to cause relaxation. The techniques described herein can thus allow for improved doping and dopant activation of upper epitaxial source/drain regions, which can improve device performance.

In an embodiment of the present disclosure, a method includes forming first nanostructures over a substrate, then forming second nanostructures over the plurality of first nanostructures. A first source/drain region is epitaxially grown adjacent the first nanostructures, and a second source/drain region is epitaxially grown over the first source/drain region and adjacent the second nanostructures. An implantation process is performed to implant impurities into the second source/drain region, wherein the implantation process forms an amorphous region within the second source/drain region. At least one rapid thermal process is performed on the second source/drain region, wherein performing each rapid thermal process recrystallizes a portion of the amorphous region.

In some embodiments, the first source/drain region is p-type and the second source/drain region is n-type. In some embodiments, the impurities are arsenic or diphosphorus. In some embodiments, after performing the at least one rapid thermal process, the first source/drain region exerts compressive strain on the first nanostructures. In some embodiments, each rapid thermal process heats the second source/drain region to a temperature less than 1250° C. In some embodiments, each rapid thermal process heats the second source/drain region for a duration of time that is less than 10 ms. In some embodiments, performing the at least one rapid thermal process fully recrystallizes the amorphous region. In some embodiments, the implantation process forms an amorphous region that extends a depth from a top surface of the second source/drain region that is between 5 nm and 15 nm.

In an embodiment of the present disclosure, a method includes forming a fin extending from a substrate, wherein the fin includes a lower nanostructure and an upper nanostructure over the lower nanostructure. Lower epitaxial source/drain regions are formed on opposite sides of the lower nanostructure, and an isolation region is formed on the lower epitaxial source/drain regions. Upper epitaxial source/drain regions are formed on the isolation region and on opposite sides of the upper nanostructure. Upper regions of the upper epitaxial source/drain regions are amorphized. A first rapid anneal process is performed to recrystallize first amorphous portions of the upper regions of the upper epitaxial source/drain regions. After performing the first rapid anneal process, a second rapid anneal process is performed to recrystallize remaining amorphous portions of the upper regions of the upper epitaxial source/drain regions.

In some embodiments, amorphizing upper regions of the upper epitaxial source/drain regions includes implanting dopants into the upper epitaxial source/drain regions. In some embodiment, the dopants are n-type dopants. In some embodiments, the first rapid anneal process activates dopants within the first portions of the upper regions of the upper epitaxial source/drain regions. In some embodiments, after performing the first rapid anneal process, a third rapid anneal process is performed to recrystallize second amorphous portions of the upper regions of the upper epitaxial source/drain regions, wherein the second amorphous portions are above the first amorphous portions. In some embodiments, the first rapid anneal process and the second rapid anneal process each include a rapid thermal anneal (RTA).

In an embodiment of the present disclosure, a method includes forming a multi-layer stack over a substrate, and patterning the multi-layer stack to form first channel regions and second channel regions over the first channel regions, wherein the first channel regions and the second channel regions include nanostructures. The method includes epitaxially growing first source/drain regions over the substrate, wherein the first channel regions extend between the first source/drain regions, wherein the first source/drain regions exerts stress in the first channel regions. The method includes forming a dielectric layer over the first source/drain regions and forming second source/drain regions over the dielectric layer, wherein the second channel regions extend between the second source/drain regions. Forming the second source/drain regions includes epitaxially growing a crystalline semiconductor material over the dielectric layer, performing an implantation process that amorphizes a portion of the crystalline semiconductor material to form an amorphous semiconductor material over the crystalline semiconductor material, and performing rapid thermal processes that recrystallize the amorphous semiconductor material. The method includes forming a first gate structure around the first channel regions and a second gate structure around the second channel regions.

In an embodiment, the first source/drain regions exert stress in the first channel regions after performing the plurality of rapid thermal processes. In an embodiment, the first source/drain regions include boron-doped silicon germanium. In an embodiment, the second source/drain regions include phosphorus-doped silicon. In an embodiment, the implantation process includes a process temperature in the range of −100° C. to 28° C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
forming a plurality of first nanostructures over a substrate;
forming a plurality of second nanostructures over the plurality of first nanostructures;
epitaxially growing a first source/drain region adjacent the plurality of first nanostructures;
epitaxially growing a second source/drain region over the first source/drain region and adjacent the plurality of second nanostructures;
performing an implantation process to implant impurities into the second source/drain region, wherein the implantation process forms an amorphous region within the second source/drain region; and
performing at least one rapid thermal process on the second source/drain region, wherein performing each rapid thermal process recrystallizes a portion of the amorphous region.

2. The method of claim 1, wherein the first source/drain region is p-type and the second source/drain region is n-type.

3. The method of claim 1, wherein the impurities comprise arsenic or diphosphorus.

4. The method of claim 1, wherein after performing the at least one rapid thermal process, the first source/drain region exerts compressive strain on the plurality of first nanostructures.

5. The method of claim 1, wherein each rapid thermal process heats the second source/drain region to a temperature less than 1250° C.

6. The method of claim 1, wherein each rapid thermal process heats the second source/drain region for a duration of time that is less than 10 ms.

7. The method of claim 1, wherein performing the at least one rapid thermal process fully recrystallizes the amorphous region.

8. The method of claim 1, wherein the implantation process forms an amorphous region that extends a depth from a top surface of the second source/drain region that is between 5 nm and 15 nm.

9. A method comprising:
forming a fin extending from a substrate, wherein the fin comprises a lower nanostructure and an upper nanostructure over the lower nanostructure;
forming lower epitaxial source/drain regions on opposite sides of the lower nanostructure;
forming an isolation region on the lower epitaxial source/drain regions;
forming upper epitaxial source/drain regions on the isolation region and on opposite sides of the upper nanostructure;
amorphizing upper regions of the upper epitaxial source/drain regions;
performing a first rapid anneal process to recrystallize first amorphous portions of the upper regions of the upper epitaxial source/drain regions; and
after performing the first rapid anneal process, performing a second rapid anneal process to recrystallize remaining amorphous portions of the upper regions of the upper epitaxial source/drain regions.

10. The method of claim 9, wherein amorphizing upper regions of the upper epitaxial source/drain regions comprises implanting dopants into the upper epitaxial source/drain regions.

11. The method of claim 10, wherein the dopants comprise n-type dopants.

12. The method of claim 10, wherein the first rapid anneal process activates dopants within the first amorphous portions of the upper regions of the upper epitaxial source/drain regions.

13. The method of claim 9 further comprising, after performing the first rapid anneal process, performing a third rapid anneal process to recrystallize second amorphous portions of the upper regions of the upper epitaxial source/drain regions, wherein the second amorphous portions are above the first amorphous portions.

14. The method of claim 9, wherein a height of the amorphized upper regions of the upper epitaxial source/drain regions is greater than half of the full height of the upper epitaxial source/drain regions.

15. The method of claim 9, wherein the first rapid anneal process and the second rapid anneal process each comprises a rapid thermal anneal (RTA).

16. A method comprising:
forming a multi-layer stack over a substrate;
patterning the multi-layer stack to form a plurality of first channel regions and a plurality of second channel regions over the plurality of first channel regions, wherein the first channel regions and the second channel regions comprise nanostructures;
epitaxially growing first source/drain regions over the substrate, wherein the first channel regions extend between the first source/drain regions, wherein the first source/drain regions exerts stress in the first channel regions;
forming a dielectric layer over the first source/drain regions;
forming second source/drain regions over the dielectric layer, wherein the second channel regions extend between the second source/drain regions, wherein forming the second source/drain regions comprises:
epitaxially growing a crystalline semiconductor material over the dielectric layer;
performing an implantation process that amorphizes a portion of the crystalline semiconductor material to form an amorphous semiconductor material over the crystalline semiconductor material; and
performing a plurality of rapid thermal processes that recrystallize the amorphous semiconductor material; and
forming a first gate structure around the first channel regions and a second gate structure around the second channel regions.

17. The method of claim 16, wherein the first source/drain regions exert stress in the first channel regions after performing the plurality of rapid thermal processes.

18. The method of claim 16, wherein the first source/drain regions comprise boron-doped silicon germanium.

19. The method of claim 16, wherein the second source/drain regions comprise phosphorus-doped silicon.

20. The method of claim 16, wherein the implantation process comprises a process temperature in the range of −100° C. to 28° C.
